(19) United States
(12) Patent Application Publication
(10) Pub. No.: US 2025/0284540 A1
(43) Pub. Date: Sep. 11, 2025

(54) Broadcasting a Host-Controlled Parameter to Circuitry Distributed at a Local-Bank Level for Usage-Based-Disturbance Mitigation

(71) Applicant: Micron Technology, Inc., Boise, ID (US)

(72) Inventors: Yang Lu, Boise, ID (US); Donald Morgan, Meridian, ID (US); Mark Kalei Hadrick, Boise, ID (US); Victor Wong, Boise, ID (US); Jacob Rice, Boise, ID (US); Kang-Yong Kim, Boise, ID (US)

(73) Assignee: Micron Technology, Inc., Boise, ID (US)

(21) Appl. No.: 19/066,931

(22) Filed: Feb. 28, 2025

Related U.S. Application Data
(60) Provisional application No. 63/561,483, filed on Mar. 5, 2024.

(51) Int. Cl. G06F 9/50

(52) U.S. Cl. CPC G06F 9/5016

(57) ABSTRACT

Apparatuses and techniques for broadcasting a host-controlled parameter to circuitry distributed at a local-bank level for usage-based-disturbance mitigation are described. In an example aspect, a memory device includes usage-based-disturbance circuitry distributed at a local-bank level and bus circuitry. The bus circuitry broadcasts information provided by a memory controller to the usage-based-disturbance circuitry. The bus circuitry provides a means of efficient communication between the mode controller and the usage-based-disturbance circuitry to enable the memory controller to control some aspect of the usage-based-disturbance mitigation operation performed by the usage-based-disturbance circuitry. This means of communication enables the memory controller to dynamically adjust an operation and/or performance of the memory device with respect to usage-based-disturbance mitigation. Some memory devices may already include the bus circuitry, which enables these techniques to be implemented without significantly increasing signal routing complexity, die size, or cost.

### CROSS-REFERENCE TO RELATED APPLICATION(S)

This application claims the benefit of U.S. Provisional Patent Application Ser. No. 63/561,483, filed on Mar. 5, 2024, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for broadcasting a host-controlled parameter to circuitry distributed at a local-bank level for usage-based-disturbance mitigation are described with reference to the following drawings. The same numbers are used throughout the drawings to reference like features and components:

FIG. 1 illustrates example apparatuses that can implement aspects of broadcasting a host-controlled parameter to circuitry distributed at a local-bank level for usage-based-disturbance mitigation;

FIG. 2 illustrates an example computing system that can implement aspects of broadcasting a host-controlled parameter to circuitry distributed at a local-bank level for usage-based-disturbance mitigation within a memory device;

FIG. 3 illustrates example data stored within rows of a memory array;

FIG. 4 illustrates an example memory device in which aspects of broadcasting a host-controlled parameter to circuitry distributed at a local-bank level for usage-based-disturbance mitigation may be implemented;

FIG. 5 illustrates an example arrangement of usage-based-disturbance circuitry on a die;

FIG. 6 illustrates an example architecture for broadcasting information provided at a global level to a local-bank level;

FIG. 7 illustrates an example transaction diagram for broadcasting information between a global level and a local-bank level of a memory device;

FIG. 8 illustrates a first example implementation of parameter update circuitry coupled to a bank-specific usage-based-disturbance circuit;

FIG. 9 illustrates a second example implementation of parameter update circuitry coupled to a bank-specific usage-based-disturbance circuit;

FIG. 10 illustrates a first example method of a memory device broadcasting a host-controlled parameter to circuitry distributed at a local-bank level for usage-based-disturbance mitigation; and

FIG. 11 illustrates a second example method of a memory device broadcasting a host-controlled parameter to circuitry distributed at a local-bank level for usage-based-disturbance mitigation.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet the demands for physically smaller memories, memory devices can be designed with higher chip densities. Increasing chip density, however, can increase the electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1”. In this example, the voltage fluctuation can cause a sense amplifier to incorrectly determine the state of the memory cell to be a “0” instead of a “1”. Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an Rth row are subjected to repeated activation, which causes one or more memory cells in an adjacent row (e.g., within an R+1 row, an R+2 row, an R−1 row, and/or an R−2 row) to change states. This effect is referred to as a usage-based disturbance. The occurrence of usage-based disturbance can lead to the corruption or changing of contents within the affected row of memory.

Some memory devices perform usage-based-disturbance mitigation in an independent manner without input from a memory controller (or a host device). In this situation, the memory controller has zero control or influence regarding the usage-based-disturbance mitigation process. The memory controller, for instance, is unable to specify or configure aspects of the usage-based-disturbance mitigation process to achieve a desired level of performance. If the memory controller may communicate with or is designed to support operation with different memory devices from different manufactures, it can be challenging for the memory controller to take into account dissimilarities regarding operation and/performance of these memory devices regarding usage-based-disturbance mitigation.

It may therefore be desirable to provide a means by which the memory controller can control some aspect of the usage-based-disturbance mitigation operation performed by a memory device. In addition to enabling the memory controller to configure some aspect of the usage-based-disturbance mitigation operation, this control can further enable the memory controller to similarly configure or adjust usage-based-disturbance-mitigation performance of various devices from different manufacturers. An architecture of the memory device, however, may not be conducive to enabling the memory controller to control an aspect of usage-based-disturbance mitigation, as further explained below.

An example memory device can have multiple instances of a circuit that performs usage-based-disturbance mitigation implemented at a local-bank level of the memory device. This architecture enables each circuit to mitigate usage-based disturbance within a particular bank (or subset of banks) that is proximate to the circuit. The multiple instances of these circuits and their distribution at the local-bank level, however, can make it challenging to route information provided by the memory controller to the individual circuits. It can be particularly challenging to implement a means of communication between the memory controller and the individual circuits without significantly increasing signal routing complexity, increasing die size, or increasing cost.

To address this and other issues regarding usage-based disturbance, this document describes aspects of broadcasting a host-controlled parameter to circuitry distributed at a local-bank level for usage-based-disturbance mitigation. In an example aspect, a memory device includes usage-based-disturbance circuitry distributed at a local-bank level and bus circuitry. The bus circuitry broadcasts information provided by a memory controller (or a host device) to the usage-based-disturbance circuitry. The bus circuitry provides a means of efficient communication between the mode controller and the usage-based-disturbance circuitry to enable the memory controller to control some aspect of the usage-based-disturbance mitigation operation performed by the usage-based-disturbance circuitry. This means of communication enables the memory controller to dynamically adjust an operation and/or performance of the memory device with respect to usage-based-disturbance mitigation.

In some memory devices, the bus circuitry can serve other purposes during other time intervals or during other modes of operation. For example, the bus circuitry can broadcast initialization information to the usage-based-disturbance circuitry and/or other circuitry implemented at the local-bank level as part of a process that initializes the memory device. Additionally or alternatively, the bus circuitry can broadcast information associated with a test to the other circuitry as part of a process that tests some aspect of the memory device. By utilizing and/or repurposing the bus circuitry to support broadcasting of a host-controlled parameter to the usage-based-disturbance circuitry during a normal operational mode, the techniques described herein can be implemented without significantly increasing signal routing complexity, increasing die size, or increasing cost.

### Example Operating Environments

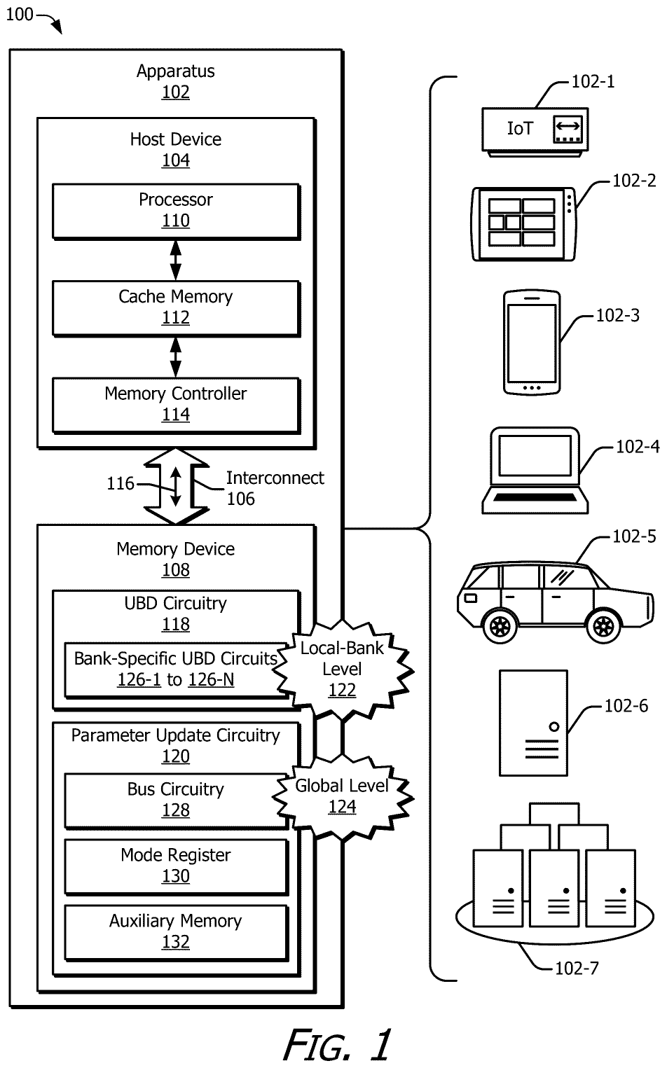

FIG. 1 illustrates, at 100 generally, an example operating environment including an apparatus 102 that can implement broadcasting a host-controlled parameter to circuitry distributed at a local-bank level for usage-based-disturbance mitigation. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, or sensor, or electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes usage-based-disturbance (UBD) circuitry 118 (UBD 118) and parameter update circuitry 120. The usage-based-disturbance circuitry 118 and the parameter update circuitry 120 can be implemented using combinations of hardware, fixed circuit circuitry, software, and/or firmware.

The usage-based-disturbance (UBD) circuitry 118 is implemented at a local-bank level 122. This means that different components of the usage-based-disturbance circuitry 118 are coupled to different banks (or different sets of banks) within a bank group. In some implementations, components implemented at the local-bank level 122 are disposed in close proximity to the corresponding bank (or banks) to simplify and/or reduce signal routing.

In contrast, the parameter update circuitry 120 is implemented at a global level 124 (or a central level). This means that components of the parameter update circuitry 120 are coupled to other components that are implemented at the local-bank level 122. Accordingly, the components of the parameter update circuitry 120 can be considered to be coupled (or indirectly coupled) to multiple banks. In some cases, the multiple banks can include all of the banks within a bank group. In some implementations, a component implemented at the global level 124 may be disposed relatively centrally to the multiple banks to more evenly distribute the routing between a component at the global level 124 and multiple components at the local-bank level 122.

Generally speaking, the usage-based-disturbance circuitry 118 mitigates usage-based disturbance within the memory device 108. The usage-based-disturbance circuitry 118 includes a plurality of bank-specific usage-based-disturbance circuits 126-1 to 126-N (bank-specific UBD circuits 126-1 to 126-N), where N is a positive integer. The bank-specific usage-based-disturbance circuits 126-1 to 126-N mitigate usage-based disturbance mitigation within its corresponding bank (or banks). The bank-specific usage-based-disturbance circuits 126-1 to 126-N represent components of the usage-based-disturbance circuitry 118 that are distributed at the local-bank level 122.

Each bank-specific usage-based-disturbance circuit 126 can include at least one counter circuit for tracking row activations, at least one comparator circuit for detecting conditions associated with usage-based disturbance, at least one queue for managing refresh operations responsive to a usage-based disturbance, and/or at least one error-correction-code (ECC) circuit for detecting and/or correcting bit errors associated with usage-based disturbance. One aspect of usage-based disturbance mitigation involves keeping track of how often a row is activated or accessed since a last refresh. In particular, the bank-specific usage-based-disturbance circuit 126 performs an array counter update procedure using the counter circuit to update an activation count associated with an activated row. During the array counter update procedure, the bank-specific usage-based-disturbance circuit 126 reads the activation count that is stored within the activated row, increments the activation count, and writes the updated activation count to the activated row. By maintaining the activation count, the bank-specific usage-based-disturbance circuit 126 can determine when to perform a refresh operation to reduce the risk of usage-based disturbance. For example, when the comparator circuit determines that the activation count meets or exceeds a threshold (e.g., a mitigation threshold), the bank-specific usage-based-disturbance circuit 126 can perform a procedure to refresh one or more rows that are near the activated row to mitigate the usage-based disturbance.

The parameter update circuitry 120 implements, at least in part, the broadcasting of a host-controlled parameter to circuitry distributed at the local-bank level 122 for usage-based-disturbance mitigation. The parameter update circuitry 120 includes bus circuitry 128, at least one mode register 130, and at least one auxiliary memory 132. The bus circuitry 128 is implemented at the global level 124 and broadcasts (e.g., passes) information provided at the global level 124 to the local-bank level 122. For usage-based-disturbance mitigation purposes, the bus circuitry 128 broadcasts information provided by the memory controller 114 (e.g., the host device 104) to the usage-based-disturbance circuitry 118. The bus circuitry 128 includes at least one communication bus and logic circuitry for formatting information that is to be communicated via the communication bus.

In some implementations, the bus circuitry 128 represents a new component that is integrated within the memory device 108 to broadcast information to the usage-based-disturbance circuitry 118. In other implementations, the memory device 108 already includes the bus circuitry 128, which is used for broadcasting other information to other components of the memory device 108. In some cases, this bus circuitry 128 is not used during a normal operational mode (e.g., during a time period in which the memory device 108 can receive a mode register write command). Sometimes the bus circuitry 128 may be utilized during initialization and/or off-line testing of the memory device 108. As such, capabilities of the bus circuitry 128 can be expanded to support the broadcasting of a host-controlled parameter to circuitry distributed at the local-bank level 122 for usage-based-disturbance mitigation. In general, any bus circuitry 128 within the memory device 108 can be operated in a manner that supports the broadcasting of the host-controlled parameter to circuitry distributed at the local-bank level 122 for usage-based-disturbance mitigation so long as the broadcasting of the host-controlled parameter does not conflict or interfere with other operations of the memory device 108 that utilize the bus circuitry 128.

The mode register 130 is also implemented at the global level 124 and stores information (e.g., at least one host-controlled parameter) that is provided by the memory controller 114. In some implementations, the mode register 130 (or multiple mode registers 130) store multiple types of information (e.g., different host-controlled parameters). The stored information enables the memory controller 114 to control at least one aspect of an operation performed by the usage-based-disturbance circuitry 118 for mitigating usage-based disturbance. In some cases, the information stored by the mode register 130 can be directly used by the usage-based-disturbance circuitry 118 to perform an operation associated with usage-based-disturbance mitigation. For example, the information can determine a value of a parameter (e.g., a mitigation threshold or an alert threshold) used in the operation. In this case, the parameter update circuitry 120 can directly provide the information to the bus circuitry 128 for broadcasting.

In other cases, the information stored by the mode register 130 can be indirectly used by the usage-based-disturbance circuitry 118 to perform the operation associated with usage-based-disturbance mitigation. For example, the information can represent an offset relative to a value of a default parameter. In this case, the parameter update circuitry 120 can further process the information and provide the resulting processed information to the bus circuitry 128 for broadcasting to the usage-based-disturbance circuitry 118. Aspects of broadcasting a host-controlled parameter to circuitry distributed at the local-bank level 122 for usage-based-disturbance mitigation can be readily detected based on a mode register write command associated with the mode register 130 causing bus circuitry 128 to broadcast information stored by the mode register 130.

The auxiliary memory 132 is implemented at the global level 124 and includes a secondary memory that is different than the memory associated with read and write commands sent by the memory controller 114. In some implementations, the auxiliary memory 132 is a non-volatile memory such as a fuse array, a flash memory, metal bits, a programmable read-only memory, a one-time programmable memory, and so on. Other implementations are also possible in which the auxiliary memory 132 is a volatile memory, such as a cache memory, a random-access memory (RAM), or a portion of a memory array of the memory device 108 that is designated for auxiliary purposes.

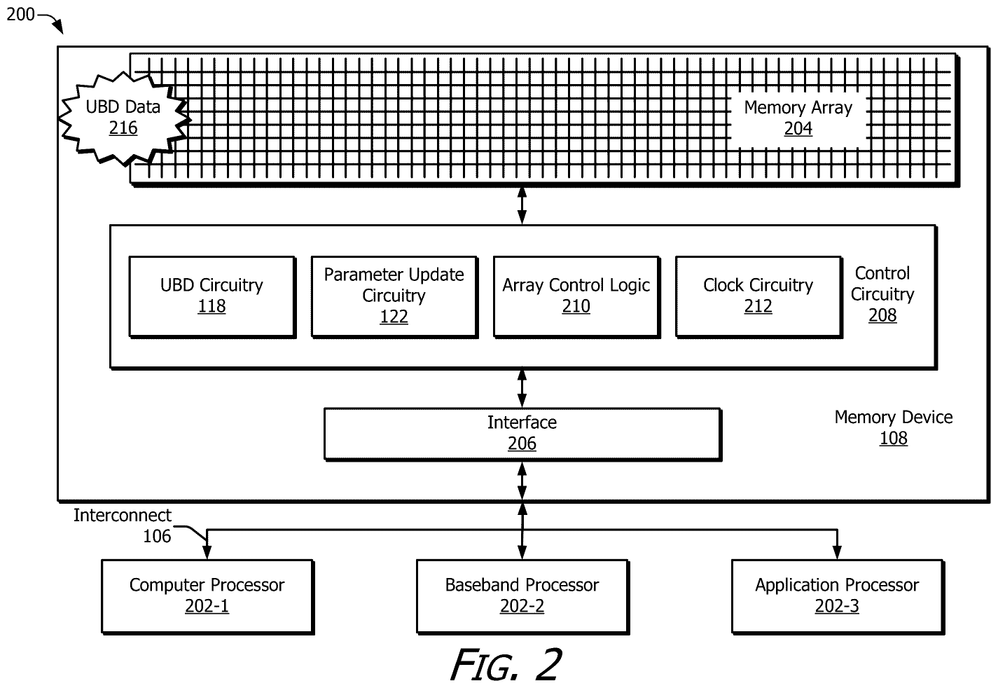

The auxiliary memory 132 stores information that can be broadcast to the local-bank level 122 using the bus circuitry 128. In some implementations, the information stored by the auxiliary memory 132 includes a default parameter associated with the information stored by the mode register 130. Additionally, the information stored by the auxiliary memory 132 can include information used during another mode of operation that differs from the normal operational mode. Example types of information can include information used for testing some aspect of the memory device 108 and applied during a test mode and/or information used to initialize some aspect of the memory device 108 and applied during an initialization mode. The mode register 130 and the auxiliary memory 132 represent non-transitory media. A computing system that includes the usage-based-disturbance circuitry 118 and the parameter update circuitry 120 is further described with respect to FIG. 2.

FIG. 2 illustrates an example computing system 200 that can implement aspects of broadcasting a host-controlled parameter to circuitry distributed at a local-bank level for usage-based-disturbance mitigation. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. For example, the control circuitry 208 can include at least one instance of array control logic 210, clock circuitry 212, the usage-based-disturbance circuitry 118, and the parameter update circuitry 120. The array control logic 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality

In one aspect, the usage-based-disturbance circuitry 118 can represent another part of the control circuitry 208. The usage-based-disturbance circuitry 118 can be coupled to a set of memory cells within the memory array 204 that store usage-based-disturbance data 216. The usage-based-disturbance data 216 can include information such as an activation count, which represents a quantity of times one or more rows within the memory array 204 have been activated (or accessed) by the memory device 108. In example implementations, each row of the memory array 204 includes a subset of memory cells that stores the usage-based-disturbance data 216 associated with that row.

The interface 206 can couple the control circuitry 208 or the memory array 204 directly or indirectly to the interconnect 106. In some implementations, the usage-based-disturbance circuitry 118, the parameter update circuitry 120, the array control logic 210, and the clock circuitry 212 can be part of a single component (e.g., the control circuitry 208). In other implementations, one or more of the usage-based-disturbance circuitry 118, the parameter update circuitry 120, the array control logic 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within a same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

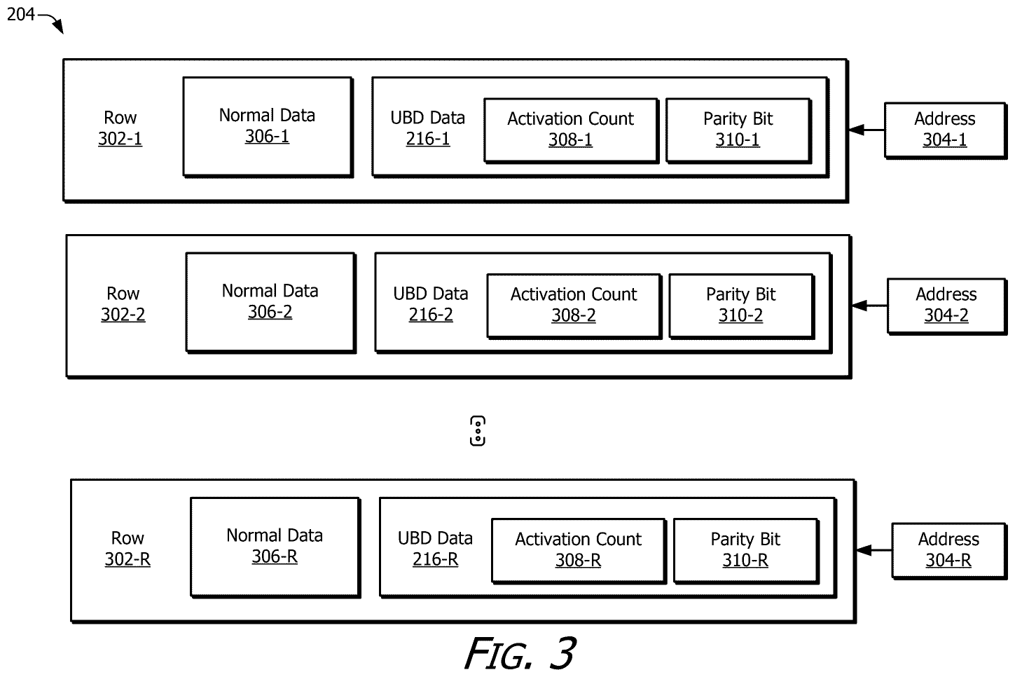

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). The memory array 204 is further described with respect to FIG. 3.

FIG. 3 illustrates example data stored within rows of the memory array 204. The memory array 204 includes multiple rows 302 of memory cells. For example, the memory array 204 depicted in FIG. 3 includes rows 302-1, 302-2 . . . 302-R, where R represents a positive integer. Each row 302 is associated with an address 304 (e.g., a row address, a memory row address, or a memory address). For example, the first row 302-1 has a first address 304-1, the second row 302-2 has a second address 304-2, and an Rth row 302-R has an Rth address 304-R.

Each of the rows 302 can store normal data 306 within a first subset of the memory cells associated with that row 302. The normal data 306 represents data that is read from or written to the memory device 108 during normal memory operations (e.g., during normal read or write operations). The normal data 306, for example, can include data that is transmitted by the memory controller 114 and is written to one or more rows 302 of the memory array 204.

In addition to the normal data 306, each of the rows 302 can store usage-based-disturbance data 216 within a second subset of the memory cells associated with that row 302. The usage-based-disturbance data 216 includes information that enables the usage-based-disturbance circuitry 118 to mitigate usage-based disturbance. In an example implementation, the usage-based-disturbance data 216 includes an activation count 308.

In this example, the first row 302-1 stores first normal data 306-1 within a first subset of memory cells of the first row 302-1 and stores first usage-based-disturbance data 216-1 within a second subset of the memory cells of the first row 302-1. The first usage-based-disturbance data 216-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 216-2 within a second subset of the memory cells within the second row 302-2. The second usage-based-disturbance data 216-2 includes a second activation count 308-2, which represents a quantity of times the second row 302-2 has been activated since a last refresh. Additionally, the Rth row 302-R stores Rth normal data 306-R within a first subset of memory cells within the Rth row 302-R and stores Rth usage-based-disturbance data 216-R within a second subset of the memory cells within the Rth row 302-R. The Rth usage-based-disturbance data 216-R includes an Rth activation count 308-R, which represents a quantity of times the Rth row 302-R has been activated since a last refresh.

The usage-based-disturbance data 216 also includes information or is formatted (e.g., coded) in such a way as to support error detection. In this example, the usage-based disturbance data 218 includes at least one parity bit 310 to enable detection of a faulty activation count 308 using a parity check. For instance, the usage-based-disturbance data 216-1, 216-2, and 216-R respectively include parity bits 310-1, 310-2, and 310-R. Other implementations are also possible in which the usage-based-disturbance data 216 is coded in a manner that supports any of the error detection tests described above, such as the error-correcting-code check.

### Example Techniques and Hardware

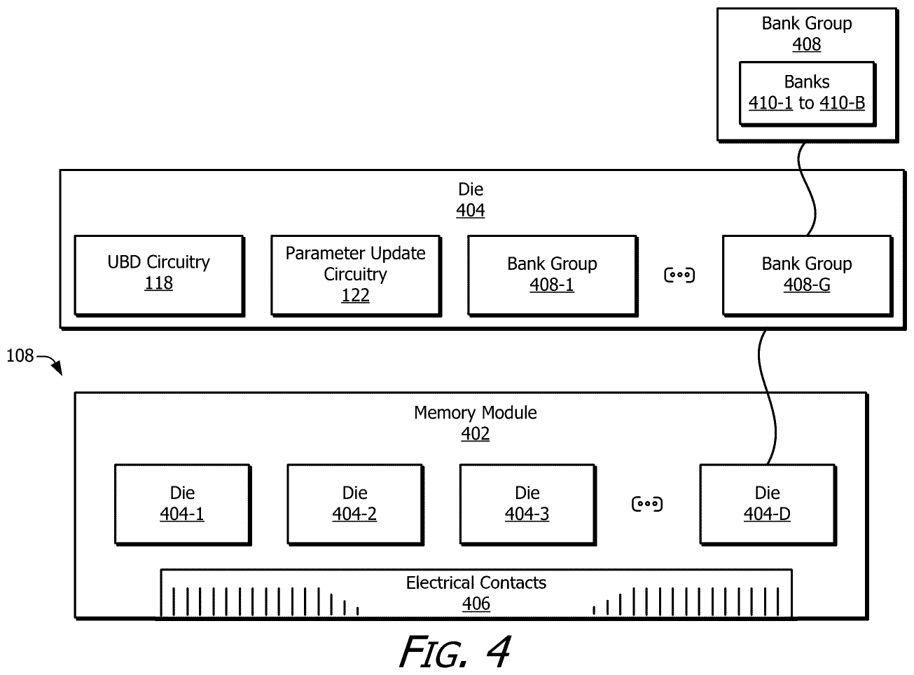

FIG. 4 illustrates an example memory device 108 in which aspects of broadcasting a host-controlled parameter to circuitry distributed at a local-bank level for usage-based-disturbance mitigation can be implemented. The memory device 108 includes a memory module 402, which can include multiple dies 404. As illustrated, the memory module 402 includes a first die 404-1, a second die 404-2, a third die 404-3, and a Dth die 404-D, with D representing a positive integer. One or more of the dies 404-1 to 404-D can include the usage-based-disturbance circuitry 118 and the parameter update circuitry 120. The memory module 402 can be a SIMM or a DIMM. As another example, the memory module 402 can interface with other components via a bus interconnect (e.g., a Peripheral Component Interconnect Express (PCIe®) bus). The memory device 108 illustrated in FIGS. 1 and 2 can correspond, for example, to multiple dies (or dice) 404-1 through 404-D, or a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size or may have different sizes. Each die 404 may be similar to another die 404 or different in size, shape, data capacity, or control circuitries. The dies 404 may also be positioned on a single side or on multiple sides of the memory module 402.

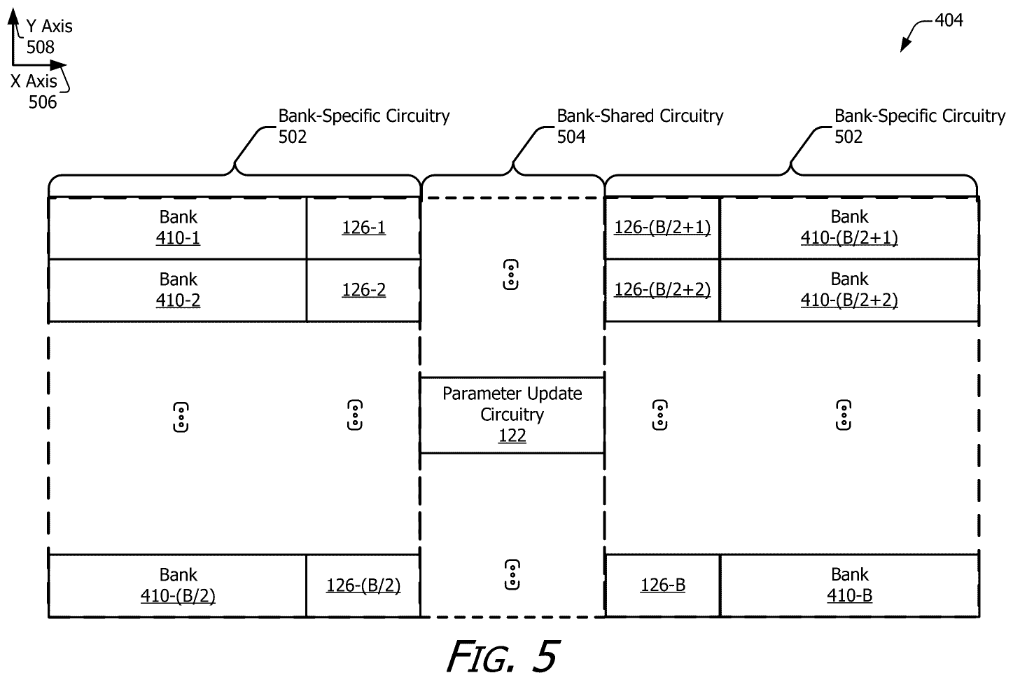

One or more of the dies 404-1 to 404-D include the usage-based-disturbance circuitry 118, the parameter update circuitry 120, and bank groups 408-1 to 408-G, with G representing a positive integer. Each bank group 408 includes at least two banks 410, such as banks 410-1 to 410-B, with B representing a positive integer. In some implementations, the die 404 includes a plurality of bank-specific usage-based-disturbance circuits 126, such as the bank-specific usage-based-disturbance circuits 126-1 to 126-N, which mitigate usage-based disturbance across the banks 410 of the bank group 408. For example, the bank-specific usage-based-disturbance circuitries (e.g., 126-1 to 126-B) can respectively mitigate usage-based disturbance for respective banks 410 (e.g., banks 410-1 to 410-B) of one bank group 408, where B is less than N. In this case, each bank-specific usage-based-disturbance circuit 126 mitigates usage-based disturbance for a single bank 410 within one of the bank groups 408. In another example, one or more of the bank-specific usage-based-disturbance circuits 126 mitigate usage-based disturbance for a subset of the banks 410 associated with one of the bank groups 408. In this case, the subset of the banks 410 includes at least two banks 410. The relationship between the banks 410 and bank-specific usage-based-disturbance circuits 126 are further described with respect to FIG. 5.

FIG. 5 illustrates an example arrangement of multiple bank-specific usage-based-disturbance circuits 126 and the parameter update circuitry 120 on a die 404. The die 404 includes bank-specific circuitry 502 and bank-shared circuitry 504. The bank-specific circuitry 502 includes components that are implemented at the local-bank level 122 and are associated with a particular bank 410 or a subset of banks 410 (e.g., a proper subset of banks 410). For example, the bank-specific circuitry 502 includes the banks 410-1, 410-2 . . . 410-(B/2), 410-(B/2+1), 410-(B/2+2) . . . 410-B and the bank-specific usage-based-disturbance circuits 126-1, 126-2 . . . 126-(B/2), 126-(B/2+1), 126-(B/2+2) . . . 126-B. The bank-specific usage-based-disturbance circuits 126-1 to 126-B are respectively coupled to the banks 410-1 to 410-B. In some cases, subsets of the banks 410-1 to 410-B are associated with different bank groups 408. In an example implementation, the die 404 includes 32 banks 410 (e.g., B equals 32). The 32 banks 410 form eight bank groups 408 (e.g., G equals 8), with each bank group 408 including four of the banks 410. In other cases, the banks 410-1 to 410-B are associated with a single bank group 408.

The bank-shared circuitry 504 includes components that are implemented at the global level 124 and are associated with multiple banks 410. These components perform operations associated with the multiple banks 410. Example components of the bank-shared circuitry 504 include the parameter update circuitry 120, which can broadcast information to the multiple bank-specific usage-based-disturbance circuits 126-1 to 126-B.

On the die 404, the bank-specific circuitry 502 may be positioned on two opposite sides of the bank-shared circuitry 504. Explained another way, the bank-shared circuitry 504 can be centrally positioned on the die 404. As such, the parameter update circuitry 120 can be positioned closer to a center of the die 404 compared to edges of the die 404. Positioning the bank-shared circuitry 504 in the center enables routing between the bank-shared circuitry 504 and the bank-specific circuitry 502 to be simplified.

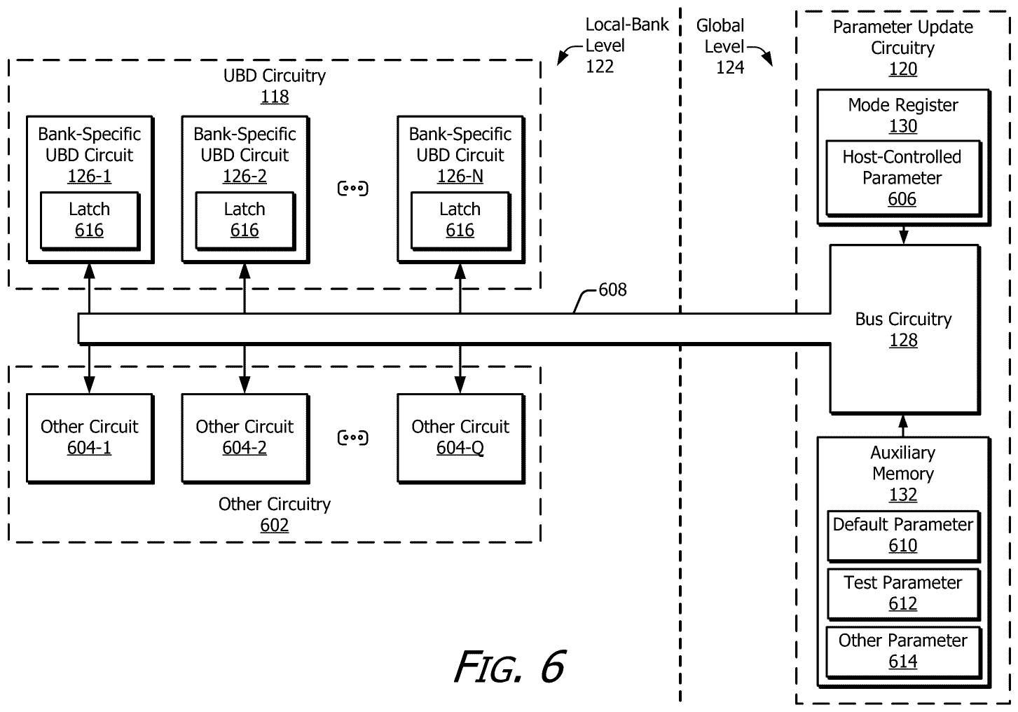

Consider a first axis 506 (e.g., x axis 505) and a second axis 508 (e.g., y axis 510), which is perpendicular to the first axis 506 In FIG. 5, the first axis 506 is depicted as a “horizontal” axis, and the second axis 510 is depicted as a “vertical” axis. Components of the bank-shared circuitry 504 are distributed across the second axis 510. A first set of the banks (e.g., banks 410-1 to bank 410-(B/2)) are arranged along the second axis 510 on a “left” side of the bank-shared circuitry 504, and a second set of the banks (e.g., banks 410-(B/2+1) to 410-B)) are arranged along the second axis 510 on a “right” side of the bank-shared circuitry 504. The bank-specific usage-based-disturbance circuits 126-1 to 126-B are positioned between the corresponding banks 410-1 to 410-B and the bank-shared circuitry 504. By positioning the parameter update circuitry 120 in a central location between the bank-specific usage-based-disturbance circuits 126-1 to 126-B, it can be easier to route signals between the parameter update circuitry 120 and the bank-specific usage-based-disturbance circuits 126-1 to 126-B. Operations of the bank-specific usage-based-disturbance circuits 126 are further described with respect to FIG. 6.

FIG. 6 illustrates an example architecture for broadcasting information provided at the global level 124 to the local-bank level 122. The architecture includes the usage-based-disturbance circuitry 118 and other circuitry 602, which are implemented at the local-bank level 122. The usage-based-disturbance circuitry 118 includes the plurality of bank-specific usage-based-disturbance circuits 126, such as the bank-specific usage-based-disturbance circuits 126-1, 126-2 . . . 126-N.

The other circuitry 602 may include one or more circuits for performing operations other than usage-based-disturbance mitigation operations. Such operations may include test mode operations in which the memory device 108 may be subjected to various tests to ensure the functionality, reliability, and performance of the memory device 108. Still other operations may include initializing components of the memory device 108 upon start-up. In this example, the other circuitry 602 includes a plurality of other circuits 604, such as the other circuits 604-1, 604-2 . . . 604-Q, where Q represents a positive integer that may or may not be equal to N.

The architecture also includes the parameter update circuitry 120, which is implemented at the global level 124. The parameter update circuitry 120 includes the bus circuitry 128, the mode register 130, and the auxiliary memory 132. In an example implementation, the mode register 130 facilitates control by and/or communication with the memory controller 114 (e.g., with the host device 104). The mode register 130 enables the memory controller 114 to provide and/or modify at least one host-controlled parameter 606 that is referenced or utilized to perform a usage-based disturbance mitigation operation by the bank-specific usage-based-disturbance circuits 126. In a sense, the host-controlled parameter 606 can be dynamically changed by the host device 104. As such, the host-controlled parameter 606 can represent an “adaptive” parameter (e.g., a “dynamic” parameter or an “adjustable” parameter).

The auxiliary memory 132 can store one or more parameters that can be used to control an operation of the memory device 108. In a scenario where the memory device 108 operates in a plurality of modes, the auxiliary memory 132 can include a plurality of memory sections configured to store a plurality of different parameters. For example, the auxiliary memory 132 can include a first memory section to store a default parameter 610 that represents a default value of the host-controlled parameter 606. The default parameter 610 can be used to initialize the usage-based-disturbance circuitry 118. The auxiliary memory 132 can also include a second memory section to store a test parameter 612 operable for testing the memory device 108. Of course, these are not meant to be limiting, as one or more other parameters 614 operable for controlling activities of the memory device 108 can also be stored in the auxiliary memory 132 and passed to the other circuitry 602. In some instances, the one or more other parameters 614 can be used to initialize the memory device 108 (or more specifically the other circuitry 602).

The bank-specific usage-based-disturbance circuits 126-1 to 126-N and the other circuits 604-1 to 604-Q are each coupled to a bus 608 (e.g., a communication bus) of the bus circuitry 128. The usage-based-disturbance circuitry 118 and the other circuitry 602 can both receive information (e.g., data or parameters) from the bus 608. In an aspect, the bus circuitry 128 can broadcast data to the usage-based-disturbance circuitry 118 and broadcast other data to the other circuitry 602 at different time periods. To ensure effective communication and reception, the data can be tagged in a manner that allows the intended circuitry to identify whether the data is designated for that circuitry. Implementing the parameter update circuitry 120 using the bus circuitry 128 reduces the amount and complexity of signal routing relative to an architecture in which each of the bank-specific usage-based-disturbance circuits 126 has separate signal routing to the mode register 130.

The bus circuitry 128 can transmit data (e.g., broadcast data) through the bus 608 to the bank-specific usage-based-disturbance circuits 126-1 to 126-N at a first specified time or in a first predetermined mode of operation of the memory device 108. The bank-specific usage-based-disturbance circuits 126-1 to 126-N may each receive the data through their respective latches 616, which are coupled to the bus 608. The latches 616 enable the bank-specific usage-based-disturbance circuits 126-1 to 126-N to receive the information that is provided by the bus circuitry 128 and store this information for future reference by the bank-specific usage-based-disturbance circuits 126-1 to 126-N. a later time during which the bank-specific usage-based-disturbance circuits 126 are activated and able to utilize the information. Thus, a need to transmit the data a plurality of times for the bank-specific usage-based-disturbance circuits 126-1 to 126-N to each get the data may be obviated.

The transmission (e.g., broadcast) can encompass various types of information tailored for particular operations. For example, the default parameter 610 can be transmitted during initialization of the memory device 108 to initialize a parameter that is used by the bank-specific usage-based-disturbance circuits 126-1 to 126-N.

During a test mode, the test parameter 612 can be transmitted to enable the execution of test procedures and performance evaluations. The bus circuitry 128 broadcasts the test parameter 612 from the auxiliary memory 132 to a test circuitry (which may be the other circuitry 602) distributed at the local-bank level 122 during the test mode. In the test mode, the memory device 108 may be subjected to various tests to ensure the functioning, reliability, and performance of the memory device 108 meet specifications. During the test mode, different types of tests can be performed, such as tests to check the basic functionality of the memory cells and logic circuits within the memory device 108, tests to verify the speed or access time of the memory device 108 to ensure it meets the specified performance criteria, tests to evaluate the power consumption and efficiency of the memory device 108, and tests to subject the memory device 108 to extreme conditions to assess its reliability and stability under adverse situations. Furthermore, other parameters 614 can be transmitted during other operations to the other circuitry 602.

In one aspect, the parameter update circuitry 120 broadcast the host-controlled parameter 606 using the bus circuitry 128 based on reception of a mode register write (MRW) command that causes data to be written to the mode register 130's operand(s) associated with the host-controlled parameter 606. The mode register write command can occur during a normal mode of operation of the memory device 108. The normal mode of operation refers to a time period during which the memory device 108 performs normal read and/or write operations based on commands received from the memory controller 114. The bus circuitry 128 can complete the broadcast of the host-controlled parameter 606 (or information derived from the host-controlled parameter 606) to the bank-specific usage-based-disturbance circuits 126-1 to 126-N during a time period that the banks 410 are idle due to the mode register write command. As such, the parameter update circuitry 120 can ensure that the latest host-controlled parameter 606 is available to the bank-specific usage-based-disturbance circuits 126-1 to 126-N prior to the end of a row active time (tRAS) and in advance of a next activation (e.g., prior to the banks 410 transitioning from an idle state to an active state).

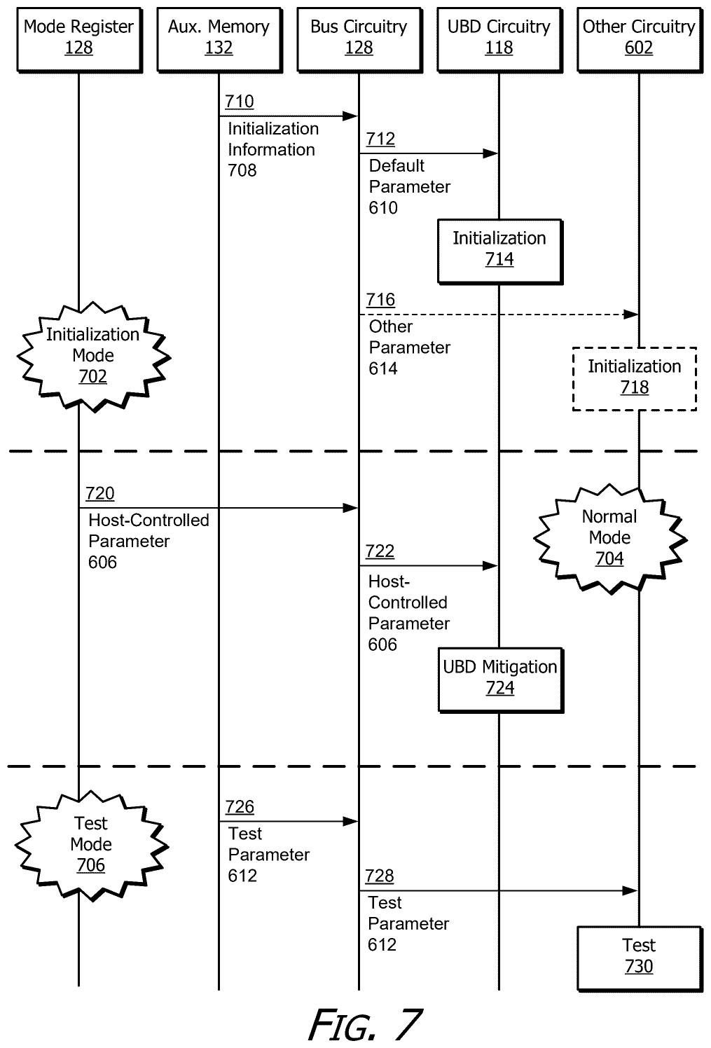

The other circuits 604-1 to 604-Q are each coupled to the bus 608 of the bus circuitry 128. When the bus circuitry 128 transmits data, at a second specified time or in a second predetermined mode of operation of the memory device 108, through the bus 608, the other circuits 604-1 to 604-Q may each receive the data. Although not explicitly shown in FIG. 6, some implementations of the other circuits 604 can include latches 616 to capture and store the information that is broadcasted by the bus circuitry 128. The broadcasting of different types of information during different time periods and/or during different modes of operation is further described with respect to FIG. 7.

FIG. 7 illustrates an example transaction diagram for broadcasting information between the global level 124 and the local-bank level 122 of the memory device 108. Three different modes of the memory device 108 are depicted in FIG. 7. These modes include an initialization mode 702, a normal mode 704, and a test mode 706, which can be performed during different time periods. The initialization mode 702 represents a mode of operation during which the memory device 108 initializes itself. The normal mode 704 represents a mode of operation during which the memory device 108 can receive commands from the memory controller 114. Example commands can include a mode register write command, a read command, and/or a write command. The test mode 706 represents a mode of operation during which the memory device 108 performs a test. Example tests can include a built-in self-test (BIST) or an off-line test. The test can evaluate functionality, reliability, and/or performance of the memory device 108.

During the initialization mode 702, the bus circuitry 128 receives initialization information 708 from the auxiliary memory 132 (Aux. memory 132) at 710. The initialization information 708 can include the default parameter 610 and/or the other parameter 614. At 712, the bus circuitry 128 broadcasts the default parameter 610 to the usage-based-disturbance circuitry 118. The usage-based-disturbance circuitry 118 performs an initialization procedure at 714, which can utilize the default parameter 610. Optionally at 716, the bus circuitry 128 broadcasts the other parameter 614 to the other circuitry 602. The other circuitry 602 can perform an initialization procedure at 718. Although the broadcasting of the default parameter 610 and the other parameter 614 are shown as separate transactions in FIG. 7, the bus circuitry 128 can optionally broadcast both the default parameter 610 and the other parameter 614 at the same time. Labels or tags associated with the default parameter 610 and the other parameter 614 can enable the usage-based-disturbance circuitry 118 and the other circuitry 602 to receive the appropriate parameter.

During the normal mode 704, the bus circuitry 128 receives the host-controlled parameter 606 from the mode register 130 at 720. At 722, the bus circuitry 128 broadcasts the host-controlled parameter 606 (or information derived from the host-controlled parameter 606) to the usage-based-disturbance circuitry 118. At 724, the usage-based-disturbance circuitry performs an operation associated with usage-based-disturbance mitigation. This operation can utilize the host-controlled parameter 606.

During the test mode 706, the bus circuitry 128 receives the test parameter 612 from the auxiliary memory 132 at 726. At 728, the bus circuitry 128 broadcasts the test parameter 612 to the other circuitry 602. At 730, the other circuitry 602 performs a test based on the test parameter 612. The operation of the bus circuitry 128 associated with mitigating usage-based disturbance is further described with respect to FIG. 7.

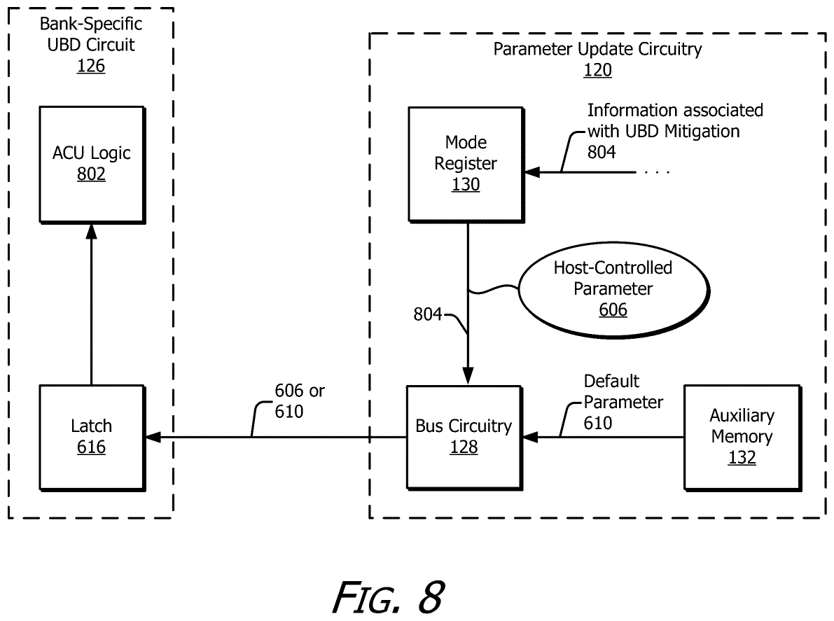

FIG. 8 illustrates an example implementation in which the parameter update circuitry 120 can directly pass information from the mode register 130 to the bank-specific usage-based-disturbance circuits 126. In this example, the parameter update circuitry 120 includes the bus circuitry 128, the mode register 130, and the auxiliary memory 132. The bank-specific usage-based-disturbance circuit 126 includes the latch 616 and array-counter-update (ACU) logic 802 (ACU logic 802). In an example implementation, the array-counter-update logic 802 can include at least one counter circuit, at least one comparator, and at least one queue.

The array-counter-update logic 802 performs an array-counter-update procedure, which reads the usage-based-disturbance data 216 and updates the usage-based-disturbance data 216 for an activated row within a corresponding bank 410. More specifically, the array-counter-update logic 802 updates an activation count 308 associated with an activated row. For instance, during the array-counter-update procedure, the array-counter-update logic 802 reads the activation count 308 that is stored within the activated row, increments the activation count 308 using the counter circuit, and writes the updated activation count to the activated row.

The array-counter-update logic 802 can also activate mitigation measures based on the usage-based-disturbance data 216 (e.g., based on the activation count 308 or the parity bit 310). In one instance, the array-counter-update logic 802 compares the activation count 308 to a threshold (e.g., a mitigation threshold) using the comparator circuit and can initiate a refresh operation based on the activation count 308 being larger than the threshold. In this case, the activated row is referred to as an aggressor row. This refresh operation can refresh one or more victim rows that are proximate to (or nearby) the aggressor row.

In some instances, the memory device 108 may be delayed in performing the refresh operation until sufficient timing resources are available. The array-counter-update logic 802 can continue monitoring the activation count 308 associated with the aggressor row. If the activation count 308 is approaching an intrinsic manufacturer limitation (e.g., an alert threshold), the array-counter-update logic 802 can initiate an alert “back-off” (ABO) procedure. During the alert back-off procedure, the memory device 108 pauses normal operations (e.g., normal read and/or write procedures requested by the host device 104) for a recovery period during which refresh management (RFM) commands or other functions may be performed in the memory device 108 to mitigate usage-based disturbance. During this recovery period, the victim rows associated with the aggressor row are refreshed.

Aspects of broadcasting a host-controlled parameter 606 to circuitry distributed at the local-bank level 122 for usage-based-disturbance mitigation enables the host device 104 to control some aspect of the usage-based-disturbance mitigation operation performed by the bank-specific usage-based-disturbance circuit 126, such as an operation performed by the array-counter-update logic 802. The specific action or extent of the specific action performed for usage-based disturbance mitigation can be controlled based on information 804 associated with usage-based-disturbance mitigation. The information 804 is provided by the host device 104 (e.g., via the memory controller 114) and stored by the mode register 130. By providing an architecture to extemporaneously and dynamically control mitigation behavior of the memory device 108 in a way that is different from a default behavior, the host device 104 can influence and/or adjust how usage-based-disturbance mitigation is performed by the memory device 108. In example aspects, information associated with the usage-based-disturbance mitigation can be used to update (change a value of) parameters (e.g., thresholds) used during the array-counter update procedure.

In the illustration of FIG. 8, an example of the information 804 can be the host-controlled parameter 606 itself. The bus circuitry 128 can broadcast the host-controlled parameter 606 to a plurality of bank-specific usage-based-disturbance circuits 126-1 to 126-N.

In an aspect, as the sizes of processors shrink, the impact of usage-based disturbance increases and the intrinsic manufacturer limitation of activation quantities between refreshes decreases. This means that mitigation operations may need to be performed more frequently. The ability to communicate not only default parameters 610 but also host-controlled parameters 606 that are specified by the host device 104 quickly and across multiple bank-specific usage-based-disturbance circuits 126 of the memory device 108 is therefore valuable.

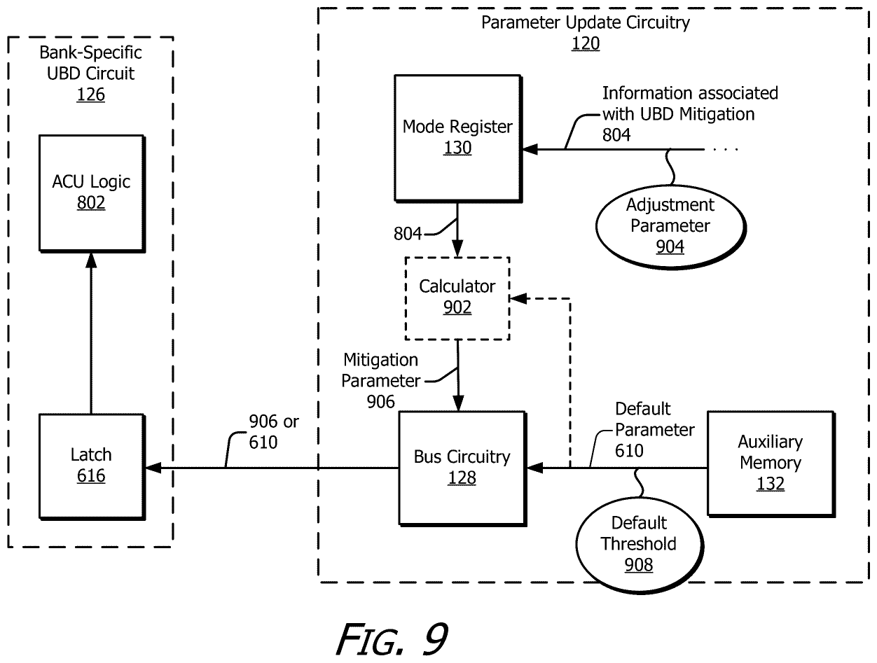

During an initialization mode 702, the bus circuitry 128 passes the default parameter 610 from the auxiliary memory 132 to the bank-specific usage-based-disturbance circuit 126. During the normal mode 704, the bus circuitry 128 passes the host-controlled parameter 606 to the bank-specific usage-based-disturbance circuit 126. In this example implementation, the host-controlled parameter 606 represents a mitigation parameter (e.g., mitigation parameter 906 of FIG. 9), which is used by the array-counter-update logic 802 to perform an operation associated with usage-based-disturbance mitigation. Other implementations of the parameter update circuitry 120 are also possible in which the host-controlled parameter 606 is not directly passed to the bank-specific usage-based-disturbance circuit 126, as further described with respect to FIG. 9.

FIG. 9 illustrates a second example implementation in which the parameter update circuitry 120 can indirectly pass information that is stored in the mode register 130 to the bank-specific usage-based-disturbance circuits 126. In this example, the parameter update circuitry 120 includes a calculator 902 in addition to the bus circuitry 128, the mode register 130, and the auxiliary memory 132. In example implementations, the calculator 902 can be implemented using a subtractor, a multiplexor, an adder, or other logic circuitry. The calculator 902 processes the information 804 stored within the mode register 130 and provides processed data to the bus circuitry 128 for broadcasting to the bank-specific usage-based-disturbance circuits 126. In this manner, the host-controlled parameter 606 that is stored within the mode register 130 is not directly passed to the bank-specific usage-based-disturbance circuit 126 and is instead used to generate other data (e.g., a mitigation parameter 906) that is broadcasted to the bank-specific usage-based-disturbance circuits 126.

In an aspect, the mode register 130 receives information 804 from the memory controller 114. This information 804 represents an adjustment parameter 904, which is the host-controlled parameter 606. The bank-specific usage-based-disturbance circuit 126 is unable to directly use the adjustment parameter 904. However, the calculator 902 uses the adjustment parameter 904 to determine (or generate) a mitigation parameter 906, which can be used by the bank-specific usage-based-disturbance circuit 126. In some examples, the calculator 902 generates the mitigation parameter 906 based on the adjustment parameter 904 and the default parameter 610. For instance, the calculator 902 uses the adjustment parameter 904 to adjust the default parameter 610.

In an example implementation, the mitigation parameter 906 can be a mitigation threshold that is used by the usage-based-disturbance circuitry 118 for mitigation operations. In particular, the array-counter-update logic 802 can compare the activation count 308 of an activated row to the mitigation parameter 906 to determine whether or not to initiate a refresh operation to mitigate usage-based disturbance. The mitigation threshold is typically set as a value that is significantly smaller than the maximum number of times a row 302 can be safely activated before a usage-based-disturbance mitigation operation becomes necessary. In this case, the default parameter 610 can represent a default threshold 908, and the mitigation parameter 906 represents an updated value of the default threshold 908 (e.g., an adaptive mitigation threshold).

In another example implementation, the mitigation parameter 906 can be an alert threshold that is used by the usage-based-disturbance circuitry 118 to trigger an alert back-off mode. During the alert back-off mode, a denial-of-service situation can occur during which the memory device 108 dedicates resources to refreshing victim rows to mitigate usage-based disturbance. The alert threshold is typically set as a value that is smaller than the maximum number of times a row 302 can be safely activated as determined by the manufacturer of the memory device 108. The alert threshold is also typically higher than the mitigation threshold. The calculator 902 can determine a value of the alert threshold by modifying a value of the default parameter 610 in accordance with the adjustment parameter 904 stored by the mode register 130.

During a first mode of the memory device 108 (e.g., during an initialization mode 702), the bus circuitry 128 selectively passes (e.g., broadcasts) the default parameter 610 from the auxiliary memory 132 to the usage-based-disturbance circuitry 118 distributed at the local-bank level 122. During a second mode of the memory device 108 (e.g., during a normal operational mode 704), the bus circuitry 128 passes the mitigation parameter 906 from the mode register 130 to the usage-based-disturbance circuitry 118. In this sense, the bus circuitry 128 can pass the default parameter 610 and the mitigation parameter 906 during different time intervals. For example, the default parameter 610 can be passed to the usage-based-disturbance circuitry 118 at initialization of the memory device 108, and the mitigation parameter 906 can be passed to the usage-based-disturbance circuitry 118 during normal operation of the memory device 108. Of course, these are not meant to be limiting, as other modes or operations and time intervals can be obtained in view of the descriptions herein.

In some implementations of the memory device 108, the parameter update circuitry 120 passes both the host-controlled parameter 606 and the mitigation parameter 906. In general, the parameter update circuitry 120 can be designed to broadcast any combination of one or more host-controlled parameters 606 and one or more mitigation parameters 906. In a first example, the parameter update circuitry 120 broadcasts one host-controlled parameter 606 and/or one mitigation parameter 906. In a second example, the parameter update circuitry 120 broadcasts multiple host-controlled parameters 606 and/or multiple mitigation parameters 906.

As shown in FIGS. 8 and 9, the bank-specific usage-based-disturbance circuit 126 can include a corresponding latch 616, which is adapted to store the broadcasted parameter (or parameters). The array-counter-update logic 802 is then provided with the stored parameter from the latch 616 when appropriate. For example, in an aspect, the array-counter-update logic 802 performs the array update procedure based on a pre-charge command. The broadcasting of the host-controlled parameter 606 and/or the mitigation parameter 906 (e.g., information derived from the host-controlled parameter 606) may thus occur prior to the pre-charge command. More specifically, the broadcasting may be based on (or occur responsive to) reception of a mode register write command that provides the information 804 for storage within the mode register 130. The mode register write command can optionally change or adjust the information 804 stored within the mode register 130.

The mode register write command is associated with a time period during which the banks 410 are in an idle mode. The parameter update circuitry 120 is able to complete the broadcasting of the host-controlled parameter 606 or the mitigation parameter 906 within the time period during which the banks 410 are in the idle mode. In effect, there is sufficient time to transmit the host-controlled parameter 606 and/or the mitigation parameter 906 to all of the bank-specific usage-based-disturbance circuits 126 before the ACU logic 802 utilizes the host-controlled parameter 606 or the mitigation parameter 906 to perform the array counter update procedure. The broadcasting can also occur during the normal mode 704. In some cases, the parameter update circuitry 120 includes additional logic that can determine that information stored in the mode register 130 has changed and activates the bus circuitry 128 to pass the information to the usage-based-disturbance circuitry 118.

### Example Method

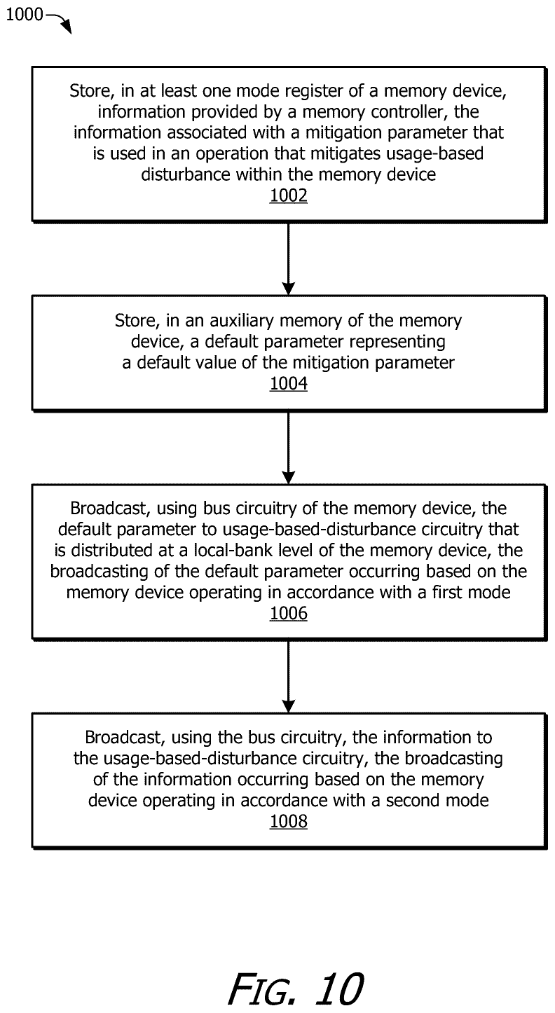

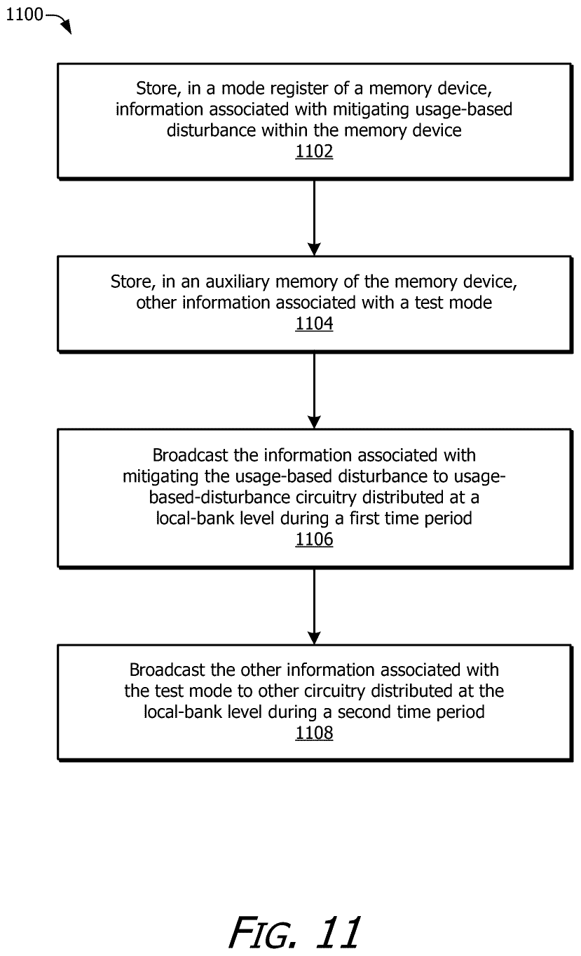

This section describes example methods for broadcasting a host-controlled parameter to circuitry distributed at a local-bank level for usage-based-disturbance mitigation with reference to the flow diagrams of FIGS. 10 and 11. These descriptions may also refer to components, entities, and other aspects depicted in FIG. 1 to FIG. 9 by way of example only. The described methods are not necessarily limited to performance by one entity or multiple entities operating on one device.

FIG. 10 illustrates a flow diagram 1000, which includes operations 1002 through 1008. In aspects, operations of the method 1000 are implemented by or with parameter update circuitry 120 as described with reference to FIG. 1 to FIG. 9. At 1002, information provided by a memory controller is stored in at least one mode register of a memory device. The information is associated with a mitigation parameter that is used in an operation that mitigates usage-based disturbance within the memory device. For example, the mode register 130 of the memory device 108 stores information 804, which represents a host-controlled parameter 606, as shown in FIGS. 6, 8 and 9. The information 804 is associated with the mitigation parameter 906 that is used in an operation that mitigates usage-based disturbance within the memory device 108. For example, the information 804 can include the mitigation parameter 906 itself (as shown in FIG. 8) or information that is used to derive the mitigation parameter 906 (as shown in FIG. 9). The mitigation parameter 906 is used by the bank-specific usage-based-disturbance circuits 126 (e.g., the array-counter-update logic 802) to mitigate usage-based disturbance within corresponding banks 410.

At 1004, a default parameter is stored in an auxiliary memory of the memory device. The default parameter represents a default value of the mitigation parameter. For example, the auxiliary memory 132 stores the default parameter 610, as shown in FIG. 6. In an example implementation, the auxiliary memory 132 is non-volatile memory, such as an array of fuses and logic for reading information stored in the fuses.

At 1006, the default parameter is broadcasted, using bus circuitry of the memory device, to usage-based-disturbance circuitry that is distributed at a local-bank level of the memory device. The broadcasting of the default parameter occurs based on the memory device operating in accordance with a first mode. For example, the bus circuitry 128 broadcasts the default parameter 610 to the usage-based-disturbance circuitry 118 that is distributed at the local-bank level 122 of the memory device 108, as shown in FIG. 7, 8, or 9. The broadcasting of the default parameter 610 occurs based on the memory device operating in accordance with a first mode, such as the initialization mode 702 of FIG. 7.

At 1008, the information is broadcasted, using the bus circuitry, to the usage-based-disturbance circuitry. The broadcasting of the information occurs based on the memory device operating in accordance with a second mode. For example, the bus circuitry 128 broadcasts the information 804 (e.g., the host-controlled parameter 606 or information derived from the host-controlled parameter 606 such as the mitigation parameter 906) to the usage-based-disturbance circuitry 118, as shown in FIG. 7, 8, or 9. The broadcasting of the information 804 occurs based on the memory device 108 operating in accordance with a second mode, such as the normal mode 704 of FIG. 7. In some cases, the broadcasting is triggered by a mode register write operation. As described above, the bus circuitry 128 can broadcast different information to the usage-based-disturbance circuitry 118 based on different modes of the memory device 108.

FIG. 11 illustrates a flow diagram 1100, which includes operations 1102 through 1108. In aspects, operations of the method 1100 are implemented by or with parameter update circuitry 120 as described with reference to FIG. 1 to FIG. 9. At 1102, information associated with mitigating usage-based disturbance within the memory device is stored in a mode register of the memory device. For example, the mode register 130 of the memory device 108 stores information 804 associated with mitigating usage-based disturbance, as shown in FIGS. 6, 8, and 9. This information 804 represents at least one host-controlled parameter 606.

At 1104, other information associated with a test mode is stored in an auxiliary memory of the memory device. For example, the auxiliary memory 132 of the memory device 108 stores a test parameter 612, as shown in FIG. 6.

At 1106, the information associated with mitigating the usage-based disturbance is broadcasted, during a first time period, to usage-based-disturbance circuitry that is distributed at a local-bank level. For example, the bus circuitry 128 broadcasts the information 804 to the usage-based-disturbance circuitry 118, which is distributed at the local-bank level 122, as shown in FIG. 6. This broadcasting occurs during a first time period, as shown in FIG. 7.

At 1108, the other information associated with the test mode is broadcasted, during a second time period, to other circuitry that is distributed at the local-bank level. For example, the bus circuitry 128 broadcasts the other information (e.g., the test parameter 612) to the other circuitry 602, which is distributed at the local-bank level 122, as shown in FIG. 6. This broadcasting occurs during a second time period, as shown in FIG. 8. The second time period is different than (e.g., does not overlap) the first time period.

For the figures described above, the orders in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIG. 1 to FIG. 8, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspect of broadcasting a host-controlled parameter to circuitry distributed at a local-bank level for usage-based-disturbance mitigation are described:

Example 1: An apparatus comprising:
a memory device comprising:
   usage-based-disturbance circuitry distributed at a local-bank level of the memory device, the usage-based-disturbance circuitry configured to perform an operation that mitigates usage-based disturbance within the memory device;
   at least one mode register configured to store information provided by a memory controller that is coupled to the memory device, the information being associated with a mitigation parameter that is utilized by the usage-based-disturbance circuitry to perform the operation that mitigates the usage-based disturbance;
   an auxiliary memory configured to store a default parameter, the default parameter representing a default value of the mitigation parameter; and
   bus circuitry implemented at a global level and coupled to the usage-based-disturbance circuitry, the at least one mode register, and the auxiliary memory, the bus circuitry configured to selectively:
      pass the default parameter from the auxiliary memory to the usage-based-disturbance circuitry in accordance with a first mode of the memory device; and
      pass the information stored in the at least one mode register to the usage-based-disturbance circuitry in accordance with a second mode of the memory device.

Example 2: The apparatus of example 1 or any other example, wherein:
the memory device further comprises a memory array; and
the usage-based-disturbance circuitry is configured to perform the operation that mitigates the usage-based disturbance within the memory array based on the information provided by the at least one mode register or the default parameter.

Example 3: The apparatus of example 2 or any other example, wherein:
the information stored by the at least one mode register comprises a mitigation threshold; and
the usage-based-disturbance circuitry is configured to:
   compare an activation count stored in an activated row of the memory array with the mitigation threshold; and
   perform the operation based on the activation count exceeding the mitigation threshold.

Example 4: The apparatus of example 2 or any other example, wherein:
the information stored by the at least one mode register comprises an alert threshold; and
the usage-based-disturbance circuitry is configured to:
   compare an activation count stored in an activated row of the memory array with the alert threshold; and
   trigger the memory device to execute an alert back-off procedure responsive to the activation count exceeding the alert threshold.

Example 5: The apparatus of example 1 or any other example, wherein the usage-based-disturbance circuitry comprises a plurality of bank-specific usage-based-disturbance circuits that are coupled to different banks of the memory device and configured to mitigate the usage-based disturbance for the different banks.

Example 6: The apparatus of example 5 or any other example, wherein:
each bank-specific usage-based-disturbance circuit of the plurality of bank-specific usage-based-disturbance circuits comprises a latch configured to store information from the bus circuitry; and
the bus circuitry comprises a communication bus coupled to the latch for each of the bank-specific usage-based-disturbance circuits.

Example 7: The apparatus of example 1 or any other example, wherein:
the information provided by the memory controller comprises an adjustment parameter; and
the apparatus further comprises:
   a calculator configured to determine a value of the mitigation parameter by modifying a value of the default parameter in accordance with the adjustment parameter.

Example 8: The apparatus of example 7 or any other example, wherein the calculator comprises a subtractor or a multiplexer.

Example 9: The apparatus of example 1 or any other example, wherein the auxiliary memory comprises a fuse array or flash memory.

Example 10: The apparatus of example 1 or any other example, wherein:
the bus circuitry is configured to pass the information from the at least one mode register to the usage-based-disturbance circuitry based on a mode-register write command associated with the at least one mode register; and
the bus circuitry is configured to pass the information from the at least one mode register to the usage-based-disturbance circuitry within a time period during which banks of the memory device are idle based on the mode-register write command.

Example 11: The apparatus of example 1 or any other example, wherein:
the memory device comprises other circuitry distributed at the local-bank level, the other circuitry configured to perform an operation associated with a test mode;
the auxiliary memory is configured to store information that is utilized by the other circuitry to perform the operation associated with the test mode; and
the bus circuitry is configured to pass the information that is utilized by the other circuitry from the auxiliary memory to the other circuitry.

Example 12: A method comprising:
storing, in at least one mode register of a memory device, information provided by a memory controller, the information associated with a mitigation parameter that is used in an operation that mitigates usage-based disturbance within the memory device;
storing, in an auxiliary memory of the memory device, a default parameter representing a default value of the mitigation parameter;
broadcasting, using bus circuitry of the memory device, the default parameter to usage-based-disturbance circuitry that is distributed at a local-bank level of the memory device, the broadcasting of the default parameter occurring based on the memory device operating in accordance with a first mode; and
broadcasting, using the bus circuitry, the information to the usage-based-disturbance circuitry, the broadcasting of the information occurring based on the memory device operating in accordance with a second mode.

Example 13: The method of example 12 or any other example, wherein:
the first mode comprises an initialization mode of the memory device; and
the second mode comprises a normal operational mode of the memory device.

Example 14: The method of example 12 or any other example, wherein the broadcasting of the information further comprises broadcasting the information responsive to a change in the information stored in the at least one mode register.

Example 15: The method of example 14 or any other example, wherein the broadcasting of the information further comprises:
receiving a mode-register write command that changes the information stored in the at least one mode register and causes banks of the memory device to become idle for a time period; and
completing the broadcasting of the information to the usage-based-disturbance circuitry within the time period during which the banks are idle.

Example 16: The method of example 12 or any other example, wherein:
the information provided by the memory controller comprises an adjustment parameter;
the broadcasting of the information to the usage-based-disturbance circuitry comprises:
   computing, by a calculator of the memory device, an updated value of the mitigation parameter using the adjustment parameter and the default parameter; and
   broadcasting the updated value of the mitigation parameter to the usage-based-disturbance circuitry.

Example 17: The method of example 12 or any other example, further comprising:
storing, in the auxiliary memory, other information associated with a test mode of the memory device; and
broadcasting, using the bus circuitry, the other information associated with the test mode to other circuitry distributed at the local-bank level, the broadcasting of the other information occurring based on the memory device operating in accordance with the test mode.

Example 18: An apparatus comprising:
a memory device comprising:
   at least one mode register configured to store information associated with mitigating usage-based disturbance within the memory device;
   an auxiliary memory configured to store other information associated with a test mode;
   bus circuitry coupled to the at least one mode register and the auxiliary memory, the bus circuitry configured to selectively:
      broadcast the information associated with mitigating the usage-based disturbance to usage-based-disturbance circuitry distributed at a local-bank level during a first time period; and
      broadcast the other information associated with the test mode to other circuitry distributed at the local-bank level during a second time period.

Example 19: The apparatus of example 18 or any other example, wherein:
the memory device is configured to selectively:
   operate in accordance with a normal operational mode during the first time period; and
   operate in accordance with a test mode during the second time period.

Example 20: The apparatus of example 19 or any other example, wherein:
the auxiliary memory is configured to store a default parameter that represents a default value of the information;
the bus circuitry is configured to selectively broadcast the default parameter to the usage-based-disturbance circuitry during a third time period; and
the memory device is configured to selectively operate in accordance with an initialization mode during the third time period.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of broadcasting a host-controlled parameter to circuitry distributed at a local-bank level for usage-based-disturbance mitigation have been described in language specific to certain features and/or methods, the subject of the appended claims is not necessarily limited to the specific features or methods described. Rather, the specific features and methods are disclosed as a variety of example implementations of broadcasting a host-controlled parameter to circuitry distributed at a local-bank level for usage-based-disturbance mitigation.

What is claimed is:

1. An apparatus comprising:
a memory device comprising:
usage-based-disturbance circuitry distributed at a local-bank level of the memory device, the usage-based-disturbance circuitry configured to perform an operation that mitigates usage-based disturbance within the memory device;
at least one mode register configured to store information provided by a memory controller that is coupled to the memory device, the information being associated with a mitigation parameter that is utilized by the usage-based-disturbance circuitry to perform the operation that mitigates the usage-based disturbance;
an auxiliary memory configured to store a default parameter, the default parameter representing a default value of the mitigation parameter; and
bus circuitry implemented at a global level and coupled to the usage-based-disturbance circuitry, the at least one mode register, and the auxiliary memory, the bus circuitry configured to selectively:
pass the default parameter from the auxiliary memory to the usage-based-disturbance circuitry in accordance with a first mode of the memory device; and
pass the information stored in the at least one mode register to the usage-based-disturbance circuitry in accordance with a second mode of the memory device.

2. The apparatus of claim 1, wherein:
the memory device further comprises a memory array; and
the usage-based-disturbance circuitry is configured to perform the operation that mitigates the usage-based disturbance within the memory array based on the information provided by the at least one mode register or the default parameter.

3. The apparatus of claim 2, wherein:
the information stored by the at least one mode register comprises a mitigation threshold; and
the usage-based-disturbance circuitry is configured to:
compare an activation count stored in an activated row of the memory array with the mitigation threshold; and
perform the operation based on the activation count exceeding the mitigation threshold.

4. The apparatus of claim 2, wherein:
the information stored by the at least one mode register comprises an alert threshold; and
the usage-based-disturbance circuitry is configured to:
compare an activation count stored in an activated row of the memory array with the alert threshold; and
trigger the memory device to execute an alert back-off procedure responsive to the activation count exceeding the alert threshold.

5. The apparatus of claim 1, wherein the usage-based-disturbance circuitry comprises a plurality of bank-specific usage-based-disturbance circuits that are coupled to different banks of the memory device and configured to mitigate the usage-based disturbance for the different banks.

6. The apparatus of claim 5, wherein:
each bank-specific usage-based-disturbance circuit of the plurality of bank-specific usage-based-disturbance circuits comprises a latch configured to store information from the bus circuitry; and
the bus circuitry comprises a communication bus coupled to the latch for each of the bank-specific usage-based-disturbance circuits.

7. The apparatus of claim 1, wherein:
the information provided by the memory controller comprises an adjustment parameter; and
the apparatus further comprises:
a calculator configured to determine a value of the mitigation parameter by modifying a value of the default parameter in accordance with the adjustment parameter.

8. The apparatus of claim 7, wherein the calculator comprises a subtractor or a multiplexer.

9. The apparatus of claim 1, wherein the auxiliary memory comprises a fuse array or flash memory.

10. The apparatus of claim 1, wherein:
the bus circuitry is configured to pass the information from the at least one mode register to the usage-based-disturbance circuitry based on a mode-register write command associated with the at least one mode register; and
the bus circuitry is configured to pass the information from the at least one mode register to the usage-based-disturbance circuitry within a time period during which banks of the memory device are idle based on the mode-register write command.

11. The apparatus of claim 1, wherein:
the memory device comprises other circuitry distributed at the local-bank level, the other circuitry configured to perform an operation associated with a test mode;
the auxiliary memory is configured to store information that is utilized by the other circuitry to perform the operation associated with the test mode; and
the bus circuitry is configured to pass the information that is utilized by the other circuitry from the auxiliary memory to the other circuitry.

12. A method comprising:
storing, in at least one mode register of a memory device, information provided by a memory controller, the information associated with a mitigation parameter that is used in an operation that mitigates usage-based disturbance within the memory device;
storing, in an auxiliary memory of the memory device, a default parameter representing a default value of the mitigation parameter;
broadcasting, using bus circuitry of the memory device, the default parameter to usage-based-disturbance circuitry that is distributed at a local-bank level of the memory device, the broadcasting of the default parameter occurring based on the memory device operating in accordance with a first mode; and
broadcasting, using the bus circuitry, the information to the usage-based-disturbance circuitry, the broadcasting of the information occurring based on the memory device operating in accordance with a second mode.

13. The method of claim 12, wherein:
the first mode comprises an initialization mode of the memory device; and
the second mode comprises a normal operational mode of the memory device.

14. The method of claim 12, wherein the broadcasting of the information further comprises broadcasting the information responsive to a change in the information stored in the at least one mode register.

15. The method of claim 14, wherein the broadcasting of the information further comprises:
receiving a mode-register write command that changes the information stored in the at least one mode register and causes banks of the memory device to become idle for a time period; and
completing the broadcasting of the information to the usage-based-disturbance circuitry within the time period during which the banks are idle.

16. The method of claim 12, wherein:
the information provided by the memory controller comprises an adjustment parameter;
the broadcasting of the information to the usage-based-disturbance circuitry comprises:
computing, by a calculator of the memory device, an updated value of the mitigation parameter using the adjustment parameter and the default parameter; and
broadcasting the updated value of the mitigation parameter to the usage-based-disturbance circuitry.

17. The method of claim 12, further comprising:
storing, in the auxiliary memory, other information associated with a test mode of the memory device; and
broadcasting, using the bus circuitry, the other information associated with the test mode to other circuitry distributed at the local-bank level, the broadcasting of the other information occurring based on the memory device operating in accordance with the test mode.

18. An apparatus comprising:
a memory device comprising:
at least one mode register configured to store information associated with mitigating usage-based disturbance within the memory device;
an auxiliary memory configured to store other information associated with a test mode;
bus circuitry coupled to the at least one mode register and the auxiliary memory, the bus circuitry configured to selectively:
broadcast the information associated with mitigating the usage-based disturbance to usage-based-disturbance circuitry distributed at a local-bank level during a first time period; and
broadcast the other information associated with the test mode to other circuitry distributed at the local-bank level during a second time period.

19. The apparatus of claim 18, wherein:
the memory device is configured to selectively:
operate in accordance with a normal operational mode during the first time period; and
operate in accordance with a test mode during the second time period.

20. The apparatus of claim 19, wherein:
the auxiliary memory is configured to store a default parameter that represents a default value of the information;
the bus circuitry is configured to selectively broadcast the default parameter to the usage-based-disturbance circuitry during a third time period; and
the memory device is configured to selectively operate in accordance with an initialization mode during the third time period.
